(19) United States
(12) Patent Application Publication
(10) Pub. No.: US 2024/0052111 A1
(43) Pub. Date: Feb. 15, 2024

(54) SELF-ASSEMBLED CONCENTRIC NANOPARTICLE RINGS TO GENERATE ORBITAL ANGULAR MOMENTUM

(71) Applicant: THE REGENTS OF THE UNIVERSITY OF CALIFORNIA, Oakland, CA (US)

(72) Inventors: Ting Xu, Berkeley, CA (US); Jie Yao, Berkeley, CA (US); Katherine Evans, Berkeley, CA (US); Qingjun Wang, Berkeley, CA (US); Emma Vargo, Berkeley, CA (US)

(73) Assignee: THE REGENTS OF THE UNIVERSITY OF CALIFORNIA, Oakland, CA (US)

(21) Appl. No.: 18/234,246

(22) Filed: Aug. 15, 2023

Related U.S. Application Data
(60) Provisional application No. 63/397,906, filed on Aug. 15, 2022.

(51) Int. Cl. C08G 83/00; C08K 5/13; C08K 3/08; G03F 7/00; B29C 33/38; B29C 71/00; B29C 33/42; B29C 33/40; B29C 39/00; B29C 39/36; B29C 39/02; B29D 11/00

(52) U.S. Cl. CPC C08G 83/008; C08K 5/13; C08K 3/08; G03F 7/0017; B29C 33/3842; B29C 71/009; B29C 33/42; B29C 33/40; B29C 39/003; B29C 39/36; B29C 39/02; B29D 11/00644; C08K 2003/0831; C08K 2201/011; B29K 2505/14

(57) ABSTRACT

Methods for generating patterned nanoparticle assemblies in thin films of supramolecular nanocomposites are provided that allow control over microdomain morphology, periodicity, and orientation by tuning the assembly kinetics and pathways of the system. Directed self-assembly (DSA) of block copolymers (BCPs) with nanoparticles formed on lithographically-patterned templates produce patterned supramolecular nanocomposite films and patterns of nanoparticles. DSA may be used to guide the formation of concentric rings with radii spanning approximately 150 nm to 1150 nm and ring widths spanning about 30 nm to 60 nm, for example. When plasmonic nanoparticles are used, ring nanodevice arrays can be fabricated in one step, and the completed devices produce high-quality orbital angular momentum (OAM).

### CROSS-REFERENCE TO RELATED APPLICATIONS

This application claims priority to, and the benefit of, U.S. provisional patent application Ser. No. 63/397,906 filed on Aug. 15, 2022, incorporated herein by reference in its entirety.

### STATEMENT REGARDING FEDERALLY SPONSORED RESEARCH OR DEVELOPMENT

This invention was made with government support under Contract No. DE-AC02-05CH11231 awarded by the U.S. Department of Energy. The government has certain rights in the invention.

### NOTICE OF MATERIAL SUBJECT TO COPYRIGHT PROTECTION

A portion of the material in this patent document may be subject to copyright protection under the copyright laws of the United States and of other countries. The owner of the copyright rights has no objection to the facsimile reproduction by anyone of the patent document or the patent disclosure, as it appears in the United States Patent and Trademark Office publicly available file or records, but otherwise reserves all copyright rights whatsoever. The copyright owner does not hereby waive any of its rights to have this patent document maintained in secrecy, including without limitation its rights pursuant to 37 C.F.R. § 1.14.

### BACKGROUND

### 1. Technical Field

This technology pertains generally to nanostructure fabrication systems and methods, and more particularly to processes and methods for generating ring-shaped nanoparticle assemblies in thin films of supramolecular nanocomposites that can produce devices with high-quality orbital angular momentum (OAM).

### 2. Background

Ring-shaped nanostructures can focus, filter, and manipulate electromagnetic waves, but these structures are challenging to incorporate into devices using standard nanofabrication techniques. “Top-down” nanofabrication processes have historically driven progress in nanodevice design and application, but these are limited by intrinsic machine and material constraints. Some of these limitations, such as fabrication of small features and complex geometries, have been addressed with a hybrid approach, where simple lithographic templates guide the self-assembly of finer features. Directed self-assembly (DSA) of block copolymers (BCPs) has successfully produced a variety of functional nanodevices, including capacitors, memory storage, and photonic crystals.

Ring-based devices include zone plates, nano lenses, and optical ring resonators. Certain memory storage devices, transistors, and sensors also use nanoscale ring features. Compared to assembly along linear patterns, DSA of curved nanostructures has distinct requirements. In order for a lamellar or cylindrical BCP microdomain to form a ring, the polymer chains need to compress along the microdomain's inner edge and stretch along its outer edge. This asymmetric distortion is energetically unfavorable. In solution, spontaneous formation of rings or toroids requires that the BCP blocks be chemically modified to experience self-attraction. BCP rings and spirals have been observed within cylindrical confinement, though only a narrow set of BCP block ratios have been studied. The confined BCP assemblies often exhibit structural degeneracy, typical of a system trapped far away from its free energy minimum state.

Directed self-assembly (DSA) of block copolymers (BCPs) on lithographically-patterned templates have been successfully used to fabricate concentric rings and spirals as etching masks. However, this method is limited by BCP phase behavior and material selection. In addition, DSA of curved features, however, has not achieved the same level of success, despite the technological importance of ring and concentric ring patterns.

Polymer nanostructures typically serve as etching masks for inorganic materials with the requisite electronic, magnetic, or optical properties. Alternatively, BCPs and inorganic nanoparticles (NPs) can be blended into nanocomposites, which offer additional advantages, including single-step fabrication as well as nanoparticle size dependent and arrangement dependent properties. Indeed, ordered nanocomposites with long-range alignment across one, two, and three dimensions have been obtained with DSA.

Therefore, there is a need for improved processes and methods for forming nanocomposite materials that will address these challenges.

### BRIEF SUMMARY

Methods for generating ring-shaped nanoparticle assemblies in thin films of supramolecular nanocomposites are provided that allow control over microdomain morphology, periodicity, and orientation by tuning the assembly kinetics and pathways of the system. Directed self-assembly (DSA) of block copolymers (BCPs) with nanoparticles on lithographically-patterned templates are used to illustrate the materials and methods. DSA may be used to guide the formation of concentric rings with radii spanning approximately 150 nm to 1150 nm and ring widths spanning approximately 30 nm to 60 nm, for example. When plasmonic nanoparticles are used, ring nanodevice arrays can be fabricated in one step, and the completed devices produce high-quality orbital angular momentum (OAM).

Nanocomposite directed self-assembly simplifies and streamlines nanofabrication by producing metal structures without etching or deposition steps. It also introduces inter-particle coupling as a new design axis. Detailed analysis of the nanoparticle ring assemblies confirms that the supramolecular system self-regulates the spatial distribution of its components, and thus exhibits a degree of flexibility absent in DSA of BCPs alone, where structures are determined by polymer-pattern incommensurability.

In one preferred embodiment, the method comprises first patterning a template with a pattern of grooves and ridges in a template platform. The patterned template, typically of concentric rings or spirals, may be milled or etched into a template platform material such as a silicon sheet. The template pattern may be designed to impart certain desirable characteristics in the final nanocomposite film structure or performance features. The patterned surface may also have a polymer layered top surface.

The patterned template is then used to structure a supramolecular nanocomposite with defined structure and characteristics. The template pattern is normally formed with trenches or grooves in the surface depth in a surface of the template of about 50 nanometers to about 75 nanometers and widths spanning between about 30 nanometers to about 60 nanometers.

The nanocomposite is formed by placing a solution of a solvent, a block copolymer, small molecules, and nanoparticles on the template. The small molecules will hydrogen bond to the block copolymer to form thin film supramolecular nanocomposites with nanoparticles via directed self-assembly. The completed supramolecular composite may be removed from the template for further use thereafter.

In one embodiment, the template is formed by gluing a silicon sheet on a first platform and then patterning the sheet with a specific pattern by lithography, milling or etching. The templated sheet may also be patterned previously before being coupled to the first platform. A sample solution with nanoparticle fillers is then placed on the template to form a patterned nanocomposite. A drop of adhesive is then applied on a second platform and the platform and drop are then placed on the exposed surface of the patterned supramolecular nanocomposite and the adhesive is allowed to dry. The patterned nanocomposite film is exfoliated from the template to the second platform by separating the first and second platforms. The template on the first platform can be reused with a new application of sample solution. It can be seen that this simple process can be easily scaled to produce many nanocomposite films simultaneously.

It has been shown that self-regulation of the small molecule distribution enables the supramolecular matrix to accommodate unfavorable curvature, confinement, and nanoparticle (NP) fillers. Incorporated particles increase the bending moduli of their host microdomains, and thus increase the energy penalty associated with curved features. To assemble successfully, the polymer matrix must accommodate both the particles and the template curvature. BCP-based supramolecules, which consist of small molecules non-covalently bonded to BCP chains, have demonstrated unparalleled flexibility in navigating interfacial interactions, NP incorporation, and geometrical confinement. Though supramolecular microstructures are visually similar to pure BCPs, small molecule redistribution makes the supramolecule sensitive to assembly kinetics. The microdomain morphology, periodicity, and orientation can all be selected by tuning the system's assembly kinetics and pathway; the system is agnostic to commensurability criteria.

In addition it has been observed that the ring-shaped nanoparticle assemblies are insensitive to the pattern feature widths, molecular weight, and NP loading, but quite sensitive to the film thicknesses and NP size. The tunability of the process and materials permits supramolecular nanocomposites to be a rapid and flexible DSA platform.

Further aspects of the technology described herein will be brought out in the following portions of the specification, wherein the detailed description is for the purpose of fully disclosing preferred embodiments of the technology without placing limitations thereon.

### BRIEF DESCRIPTION OF THE DRAWINGS

The technology described herein will be more fully understood by reference to the following drawings which are for illustrative purposes only:

FIG. 1 is a functional block diagram of a method for producing a patterned supramolecular nanocomposite film with defined structure and characteristics according to one embodiment of the technology.

FIG. 2 is a schematic diagram of a three concentric ring template, with a trench width (Wₜ) of 200 nm, mesa width (Wₘ) of 150 nm, and a 50 nm etch depth. The order parameter, microdomain period and defect density are plotted radially from the center of the pattern and the shaded bars give the trench positions. The dashed lines show control values from an un-patterned sample.

FIG. 3A is a schematic diagram depicting the first step in the film preparation and exfoliation process according to one embodiment of the technology.

FIG. 3B is a schematic diagram depicting the second step in the film preparation and exfoliation process of FIG. 3A.

FIG. 3C is a schematic diagram depicting the third step in the film preparation and exfoliation process of FIG. 3A.

FIG. 4 is AFM micrograph of a nanocomposite self-assembled on the ring-patterned substrate. The lighter microdomains are PS and the darker microdomains are P4VP(PDP)+NPs.

FIG. 5 is a micrograph of the nanocomposite self-assembled on the ring-patterned substrate with defect density values labeled with black dots.

FIG. 6 is a schematic optical setup used to test the interactions of the device with transmitted light. Light passes through a diffuser, a linear polarizer (LP), a quarter wave plate (QWP), and a first lens (L1) before it reaches the sample. Beyond the sample, light is focused with an optical lens (OL) before being split by a beam splitter (BS). The first optical path uses a second lens (L2, f=100 mm) to achieve 25× magnification. The second optical path passes through a different lens (L3, f=1000 mm) to achieve 250× magnification. Optical microscope image of the exfoliated sample. Device arrays are boxed in white. An image captured by CCD1, with a magnification of 25×, and an image captured by CCD2, with a magnification of 250×, are also provided. The characteristic donut-shaped patterns of OAM are clearly seen.

FIG. 7 is a comparison of an AFM micrograph of the nanocomposite self-assembled on P150, the same micrograph with labeled defects and plots of the order parameter, microdomain period, and defect density plotted radially from the pattern's center. The dashed lines show control values from a non-patterned sample; the shaded bars give the trench positions.

FIG. 8 is a comparison of an AFM micrograph of the nanocomposite self-assembled on P100, the same micrograph with labeled defects and plots of the order parameter, microdomain period, and defect density plotted radially from the pattern's center. The dashed lines show control values from a non-patterned sample; the shaded bars give the trench positions.

FIG. 9 is a comparison of an AFM micrograph of the nanocomposite self-assembled on P200, the same micrograph with labeled defects and plots of the order parameter, microdomain period, and defect density plotted radially from the pattern's center. The dashed lines show control values from a non-patterned sample; the shaded bars give the trench positions.

FIG. 10 is a schematic diagram of microdomain bending and three possible response modes: i, no PDP redistribution; ii, PDP redistributes within neighboring P4VP(PDP) microdomains; and iii, PDP redistributes within all neighboring microdomains.

FIG. 11 is a plot of strain vs. curvature radius for assemblies of NC1 under redistribution modes i, ii, and iii.

FIG. 12 is a plot of strain vs. curvature radius for assemblies of NC2 under redistribution modes i, ii, and iii.

FIG. 13 is a plot of all observed states of the NC1 nanocomposite on patterns P100, P150, and P200.

FIG. 14 is a plot of all observed states of the NC2 nanocomposite on patterns P100, P150, and P200. The gray stair-step pattern in FIG. 13 and FIG. 14 shows the commensurate state closest to the equilibrium periodicity for all trench widths. The marker size is scaled by the number of times a state was observed; i.e., the most common states are drawn with the largest markers.

### DETAILED DESCRIPTION

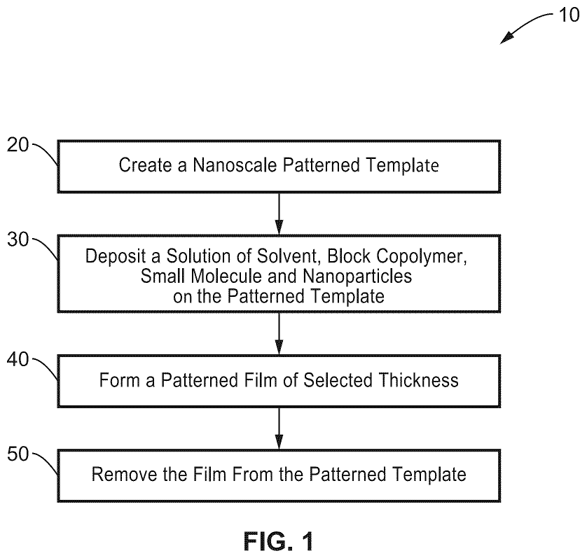

Referring more specifically to the drawings, for illustrative purposes, supramolecular nanocomposite compositions, systems and methods of fabrication and use are generally shown. Several embodiments of the technology are described generally in FIG. 1 to FIG. 14 to illustrate the characteristics and functionality of the compositions, systems, materials and methods. It will be appreciated that the methods may vary as to the specific steps and sequence and the systems and apparatus may vary as to structural details without departing from the basic concepts as disclosed herein. The method steps are merely exemplary of the order that these steps may occur. The steps may occur in any order that is desired, such that it still performs the goals of the claimed technology.

Turning now to FIG. 1, a functional block diagram of a method 10 for producing a patterned supramolecular nanocomposite is shown. At block 20, a nanoscale patterned template is produced. In one embodiment, the template is created using electron beam lithography or by etching.

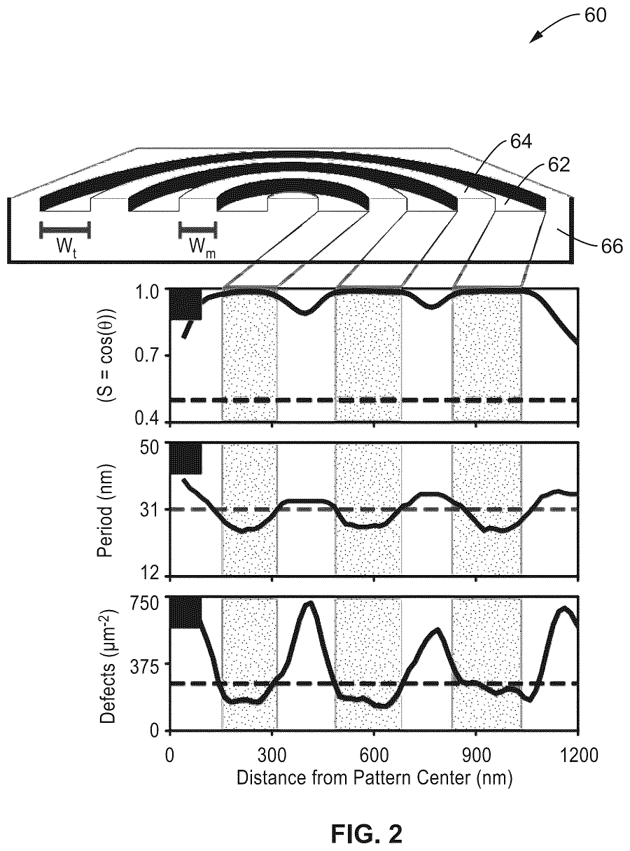

The configuration of the template pattern can be selected to provide a final supramolecular nanocomposite film structure with desired size and functional characteristics. For example, concentric rings, spirals and many other structures can be patterned in the template at block 20. As illustrated schematically in FIG. 2, a template structure 60 can have a pattern of one or more concentric rings formed with grooves or trenches 62 and mesas 64 in the template platform 66. In the three concentric ring structure 60 illustrated in FIG. 2, the platform 66 has multiple trenches 62 with a trench width (Wₜ) and a mesa width (Wₘ) and a depth. The dimensions of the trench widths (Wₜ), mesa widths (Wₘ) and depths of the patterned template can be selected to impart desired characteristics. The microdomain morphology, periodicity, and orientation can all be selected by tuning the system's assembly kinetics and pathway as shown in the corresponding graphs of FIG. 2.

In addition, the order parameter, microdomain period, and defect density are plotted radially from the center and the shaded bars represent the trench position in FIG. 2. The dashed lines in the plots represent control values from an un-patterned sample in FIG. 2.

The dimensions of the trench widths, mesa widths and depths of the template structure 60 are preferably in nanoscale sizes. In the schematic of the concentric ring template illustrated in FIG. 2, the trench width (Wₜ) was 200 nm, the mesa width (Wₘ) was 150 nm, and the etch depth was 50 nm. Trench depths are preferably between about 50 nm and about 75 nm. However, each of these dimensions are tunable to produce features in the film of desired size and characteristics.

A composition of a solvent, a block copolymer, a small molecule and nanoparticles is provided at block 30 of FIG. 2. The solvent should be compatible with the selected block copolymer, small molecule and nanoparticle. One preferred solvent chloroform. Many block copolymers are known in the art. One preferred block copolymer used to illustrate the technology is polystyrene-b-poly(4-vinylpyridine) (PS-b-P4VP). Another preferred block copolymer is PS(19 kDa)-b-P4VP(5.2 kDa) or PS(50 kDa)-b-P4VP(17 kDa). The molecules that are suitable for use as small molecules in the formulation are most organic small molecules. One preferred small molecule is 3-pentadecylphenol (PDP). The nanoparticles may be made of metals such as iron or gold as well as from inorganic materials. In one embodiment, the nanoparticles are alkyl-passivated. The nanoparticles are preferably sized between about 2.5 nanometers to 9.5 nanometers. Preferred nanoparticles may also be sized at about 5 nanometers in diameter.

In one embodiment, more than one type of small molecule is used in the composition. In another embodiment, more than one type and size of nanoparticle is used in the composition. In a further embodiment, two different sizes of nanoparticles of the same material are used in the composition. The choice and concentration of each component of the composition can also be manipulated to influence the morphology and characteristics of the composition and final film.

The prepared composition solution is then deposited onto the patterned surface of the template at block 30 of FIG. 1. The composition forms a supramolecular nanocomposite film of a controllable thickness by directed self-assembly that adopts a morphology influenced by the patterned template at block 40. The thickness of the final nanocomposite film is preferably greater than about 50 nm. The deposited supramolecular nanocomposite film may be dried and processed. In one embodiment, the composite is processed by solvent vapor annealing at block 40.

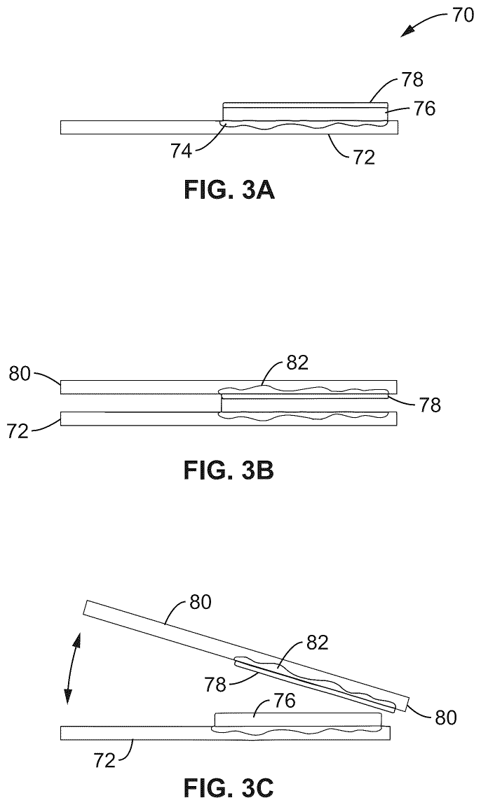

The final supramolecular nanocomposite film is removed from the template at block 50 of FIG. 1. In one embodiment, the processed nanocomposite film is removed from the template by exfoliation. This procedure can be adapted for producing multiple films from a single patterned template. One process for producing multiple nanocomposite films is shown in FIG. 3A through FIG. 3C. The process 70 begins with a pattern platform 72. A patterned substrate 76 is mounted to the patterned template 76 with an adhesive layer 74. The top surface of the patterned template 76 has a defined nanoscale pattern. A film forming solution is applied to the top surface of the patterned template 76 to form a supramolecular nanocomposite film 78. The prepared film 78 may be annealed or otherwise processed in place to produce a final nanocomposite film.

As shown in FIG. 3B, a second platform 80 is provided with an adhesive 82 on its surface. The adhesive 82 of platform 80 is coupled to the prepared nanocomposite film 78 and allowed to bond fully with the film.

Once the adhesive 82 has bonded with the nanocomposite film 78, the second platform 80 is separated from the template platform 72 thereby removing the nanocomposite film 78 from the patterned template 76 as illustrated in FIG. 3C. The patterned template 87 is then available to pattern a new nanocomposite film. The removed patterned nanocomposite film 78 can remain or be removed from the second platform 80 for use in selected devices.

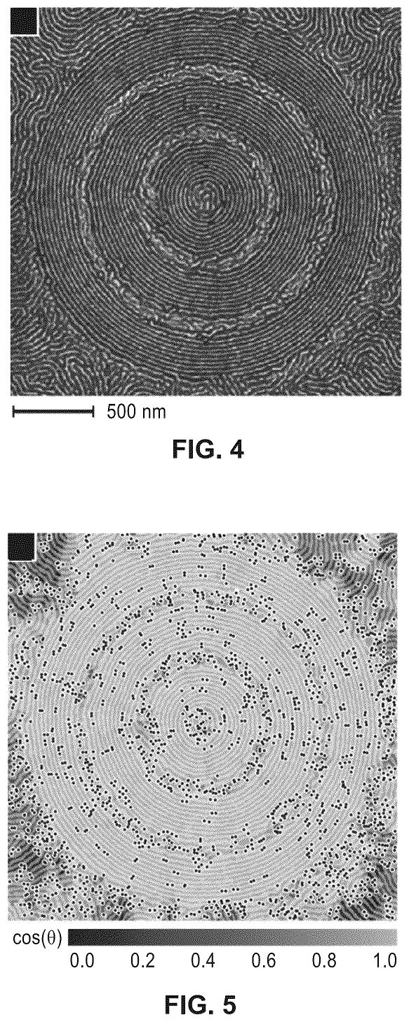

An example of a patterned concentric ring construct self-assembled on a ring template is shown in the AFM micrograph of FIG. 4. The lighter microdomains are PS material and the darker microdomains are P4VP(PDP)+NPs. The same construct is shown in FIG. 5 with the defects labeled with black dots.

The technology described herein may be better understood with reference to the accompanying examples, which are intended for purposes of illustration only and should not be construed as in any sense limiting the scope of the technology described herein as defined in the claims appended hereto.

### Example 1

In order to demonstrate the structure and functionality of the patterned supramolecular nanocomposites, films were assembled across a variety of patterns and conditions and analyzed. The supramolecules were constructed using a BCP, polystyrene-b-poly(4-vinylpyridine) (PS-b-P4VP), and the small molecule 3-pentadecylphenol (PDP), which hydrogen-bonds with the 4VP monomer. The PDP:4VP ratio was 2, so at least half of the small molecules were unbonded at any time. The PS-b-P4VP(PDP) supramolecules were blended with 3 vol % alkyl-passivated NPs, which have favorable interactions with the P4VP(PDP) microdomains.

The PS(19 kDa)-b-P4VP(5.2 kDa) (PDI=1.06) and PS(50 kDa)-b-P4VP(17 kDa) (PDI=1.15) were purchased from Polymer Source, Inc. 3-Pentadecylphenol (90%-95%) was purchased from ACROS Organics. Chloroform (Amylene as preservative) was purchased from Fisher Scientific. Hydrogen tetrachloroaurate (III) trihydrate (HAuCl₄·3H₂O, Sigma-Aldrich, 99.995%, trace metals basis), oleylamine (Sigma-Aldrich, technical grade, 70%), tert-butylamine-borane (TBAB) complex (Aldrich, 97%), 1,2,3,4-tetrahydronaphthalene (tetralin, anhydrous, 99%), 1-dodecanethiol (Sigma-Aldrich, 98%) methanol (Fisher Scientific, analytical reagent grade), chloroform (Sigma-Aldrich, contains 100-200 ppm amylenes as stabilizer, ≥99.5%) and acetone (Sigma-Aldrich) were used to synthesize the 5 nm gold NPs, using previously published methods. The 5 nm iron oxide NPs that were dispersed in chloroform were purchased from Ocean Nanotech.

Two nanocomposites were evaluated, forming cylindrical PS microdomains with equilibrium periodicities of 31 nm and 57 nm, respectively (Table 1). The first nanocomposite composition, denoted as NC1, consisted of a 19 kDa PS block and a 5.2 kDa P4VP block.

The second nanocomposite (NC2) was constructed from a BCP containing 50 kDa PS and 17 kDa P4VP. The NP core chemistry has no effect on the self-assembly process, so iron oxide nanoparticles were used for the systematic DSA studies, and gold nanoparticles were used to fabricate the optical devices.

The ring templates have three trenches and two mesas, with feature widths from 100-200 nm and an etch depth of 50 nm (Table 2). The circular trenches were fabricated using electron beam (e-beam) lithography. A variety of patterns were fabricated.

Supramolecular solutions were prepared by dissolving the polymer and the small molecule in chloroform and stirring for 72 hours. Thin films with film thicknesses of approximately 55 nm were prepared via spin-coating and solvent vapor annealing, using previously-published methods. Gold NPs were used for the optical measurements, and iron oxide NPs were used for the AFM studies. It was established that the composition of the NPs does not affect their assembly behavior, as long as their ligand chemistries are consistent.

### Example 2

To evaluate and characterize the quality of assembly of supramolecular nanocomposites, the DSA of several supramolecular nanocomposites within a concentric ring template was evaluated. The template, selected to be compatible with the requirements of OAM, consisted of three 200 nm trenches separated by two 150 nm mesas as illustrated schematically in FIG. 2.

The supramolecular nanocomposite samples were prepared by spin-coating the composite onto the prepared patterned templates. The films were approximately 60 nm in thickness and were annealed under chloroform vapor to a solvent fraction of 35%. The annealing process took less than 10 minutes. During annealing, the PS cylinders curved into toroids, with near-perfect alignment within the three trench regions. The microdomains on the raised mesas also became aligned, albeit to a lesser degree, with a high density of defects and a slightly larger periodicity. To quantify local microdomain alignment in the annealed samples, the order parameter S=cos θ, where θ is the angle between a polymer microdomain and the orientation of the underlying template was defined. Quantitative image analysis of an atomic force microscopy (AFM) micrographs supported the qualitative observations. Specifically, that the radially-averaged S was above 0.96 within the three trenches, very close to a perfect value of 1.0, and above 0.88 within the two mesas. Past the outer trench, the aligning effect of the pattern decayed gradually, and the features became randomly oriented (S≈0.5) within five microdomain periods.

On a flat substrate, the supramolecular nanocomposite formed isotropically-oriented cylindrical microdomains with a period of 31 nm. When the patterned substrate was used, however, the microdomain periodicity was modulated by the underlying ring pattern. Within the trenches, the periodicity decreased up to 19% to form cylinders with a period of 25 nm.

Complementary microdomain swelling was observed on the mesas and surrounding substrate, where the periodicity expanded up to 13% to form microdomains with a period of 35 nm. Periodicity changes within 10% of the equilibrium are routinely observed in BCP DSA whenever polymer chains must stretch or compress to achieve commensurability with the template. However, oscillations between increased and decreased periodicity were rather rare. In templated BCP systems, microdomain stretching or compression starts at the pattern's edge and propagates inward. Here, the increased periodicity past the template's edge suggests that the supramolecular system achieves commensurability through a different mechanism. Instead of relying on entropically-unfavorable polymer chain deformation, free PDP is expelled from the trenches and collects on the mesas. Regions with lower concentrations of PDP have smaller equilibrium periodicities and lower bending moduli, so the confined supramolecules can potentially expel PDP until they fit neatly within the trenches. This global self-regulation process is consistent with previous results observed using linear trench templates. These observations are also consistent with studies of homopolymer-BCP blends, where homopolymers were shown to distribute nonuniformly within the BCP to reduce the entropic penalties associated with domain curvature and cross-sectional mismatch.

Device-driven applications of DSA require high-quality pattern transfer with low defect densities. Within cylindrical morphologies, defects are defined as microdomain branches or terminal points. For this specific system, the un-patterned control sample has an average of 262 defects per μm², that were distributed randomly across the sample surface.

The templated sample, conversely, had a spatially-patterned defect distribution. Just as the microdomain period oscillates across the trenches and mesas, the defect density decreased by more than 30% within the trenches, then surpassed the equilibrium defect density on the mesas and surrounding substrate. The increased defectivity is not due to poor ordering, because the order parameter S remains above 0.78 across the entire pattern. Within the regions of high defectivity, i.e. the mesas, the microdomain periodicity was increased, and the aspect ratio of the PS cylinders was substantially reduced. These results suggest that the increased P4VP(PDP) fraction on the mesas caused a cylinder-to-sphere morphological transition. This morphological transition may thus be used to infer the spatial distribution of PDP.

### Example 3

To further characterize the nanocomposites, the optical properties of the templated concentric rings of the nanocomposites were evaluated. The DSA of the supramolecular nanocomposite is not limited to a single pattern and can be readily scaled up. This was demonstrated by fabricating a 10×10 array of patterns on one wafer. After assembly, the concentric rings of the supramolecular nanocomposite were exfoliated from the silicon substrate. The exfoliated films could subsequently be transferred anywhere, such as a fiber tip, demonstrating the versatility of the fabrication process.

In this Example, the exfoliated film modulated circularly-polarized light to produce orbital angular momentum (OAM). Optical modes carrying OAM are typically represented by a helical wavefront and a phase singularity and have a broad range of applications, including communication, particle manipulation, astronomy, imaging, and quantum optics.

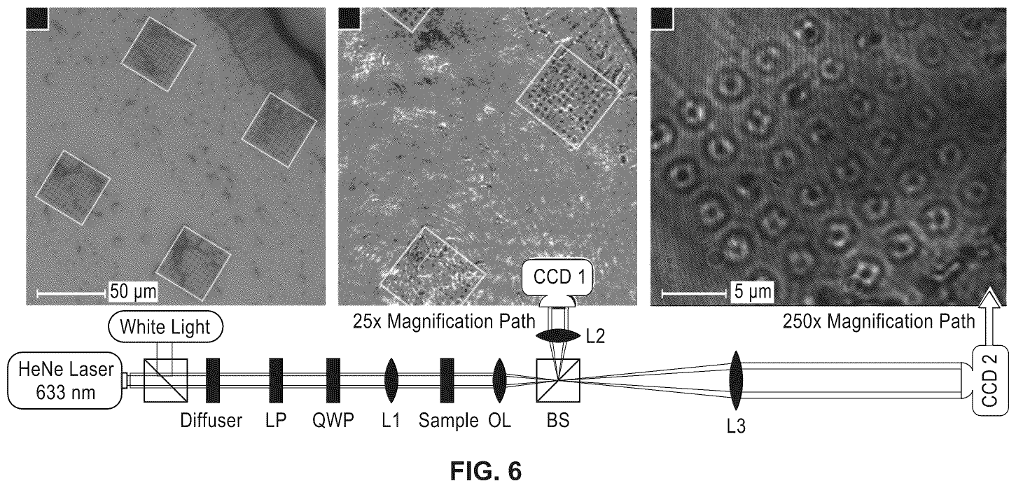

To measure optical transmission through the patterned NP assembly and the OAM order of the transmitted light, a high-magnification microscopy setup was designed. The set-up, shown in FIG. 6, includes two magnification paths: a 25× magnification path to find the sample and a 250× magnification path to observe the OAM. Images of the sample under the two optical paths were obtained. When circularly-polarized light was transmitted through the nanocomposite with 3 vol % gold NPs, the assembly successfully produced light with OAM, identifiable by its donut-shaped intensity distribution and its good agreement with full-wave simulations. The clear array of donut shapes that were observed suggested that OAM generation with these DSA devices is a novel approach with improved resolution and flexibility compared to previous, top-down-fabricated nanodevices.

In order to understand the origin of OAM, a circularly-polarized beam of light may be represented as a linear superposition of radially-polarized and azimuthally-polarized vortex beams. In a cylindrical coordinate system, a left-hand or right-hand circularly-polarized beam (LHC or RHC) with a topological charge of 1 may be expressed as:

\vec{E_{LHC}}=e^{jφ}(\vec{eᵣ}+j\vec{e_{φ}})

\vec{E_{RHC}}=e^{-jφ}(\vec{eᵣ}−j\vec{e_{φ}})

where eᵣ and e_{φ} are the amplitudes of unit vectors in the radial and azimuthal directions, respectively. The gold NP concentric ring structures cause higher transmittance of the radially-polarized component, so light leaves the nanocomposite device as a radially-polarized vortex beam.

A finite element method (FEM) simulation of the patterned device was used to further study the generation of OAM. The intensity and phase distributions of the electric field in the transmission region were evaluated and the observed donut-shaped intensity and the vortex phase distribution again confirm the generation of Laguerre-Gaussian modes with OAM. Since the incident light was circularly-polarized light with no vortex, the donut-shaped intensity distribution on the transmission side indicates phase singularity and the generation of OAM with a topological charge of ±1, depending on the handedness of the incident circularly-polarized light.

### Example 4

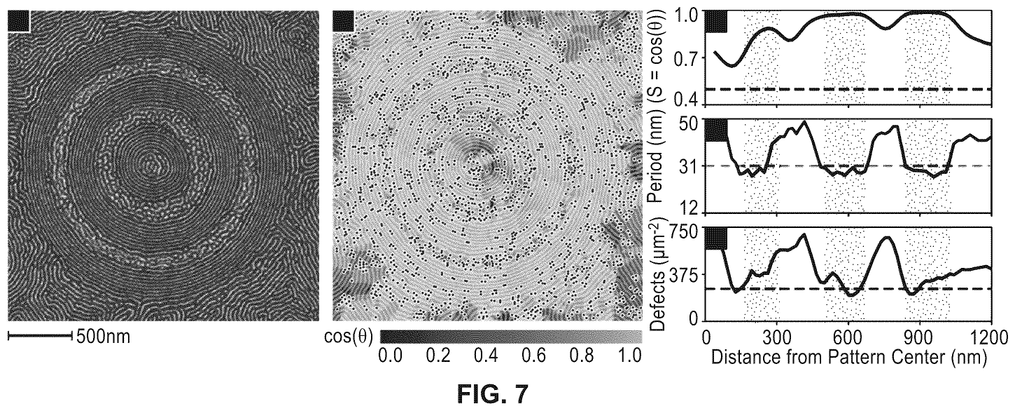

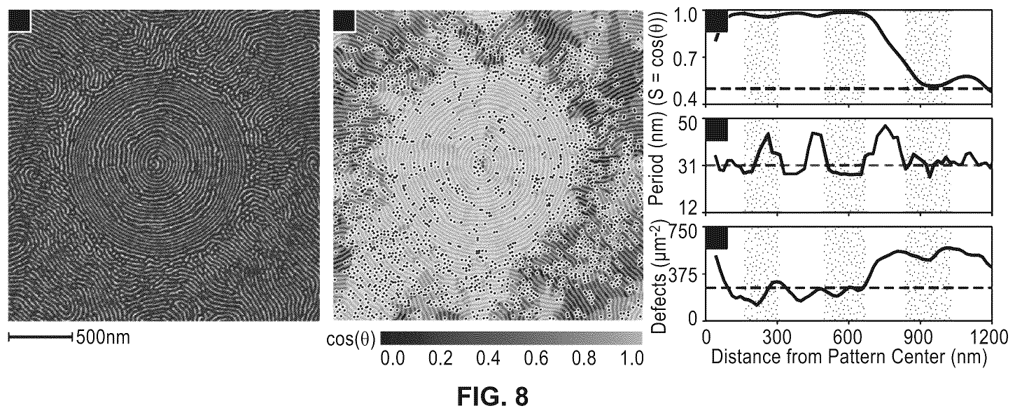

In comparison to DSA of BCP-only systems, where the template dimensions dictate the microdomain periodicity, the supramolecular nanocomposite system is not constrained by pattern-polymer commensurability. To this end, the same nanocomposite composition was used for DSA within two additional ring patterns: P150 (Wₜ=150 nm and Wₘ=200 nm) shown in FIG. 7 and P100 (Wₜ=100 nm and Wₘ=100 nm) shown in FIG. 8. The supramolecular nanocomposite assembled successfully in both P150 and P100.

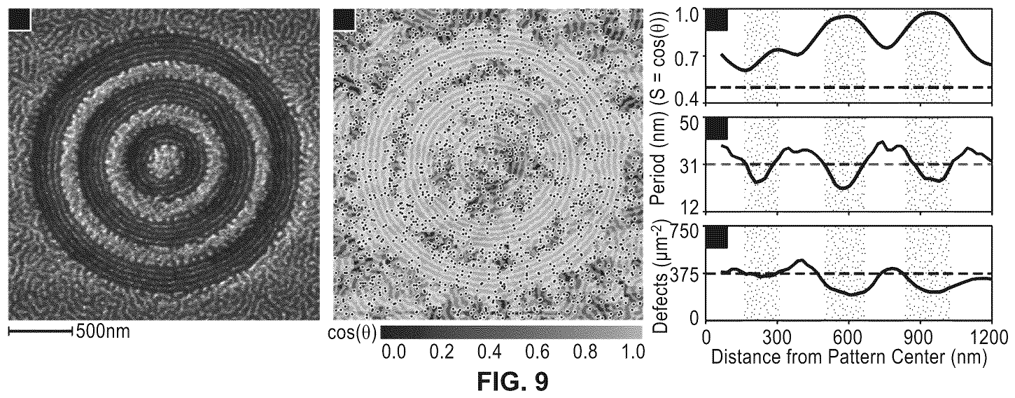

Compared to the original ring pattern of P200 shown in FIG. 9, the two new patterns have thinner trenches with tighter radii of curvature. The periodicity oscillations noted within P200 are observed in both smaller patterns as well, consistent with the proposed PDP redistribution mechanism.

In the area surrounding P100, the periodicity converged to the system's equilibrium value within 200 nm, or about 6 microdomain periods. Unlike the assemblies on the two larger patterns, the defect density of the nanocomposite guided by P100 was effectively constant across the patterned area. The cylindrical microdomains are aligned across the trenches and mesas, forming a continuous series of rings and spirals. The presence of periodicity oscillations suggests that the supramolecule was still incommensurate with the underlying trench pattern. However, for this pattern, much of the excess PDP appears to have been ejected from the pattern entirely, reducing the PDP accumulation on the mesas. This suggests self-regulation across an astonishing distance of 500 nm, or 20 microdomain periodicities.

The ring templates were used to guide another nanocomposite system, NC2, with an equilibrium periodicity of 57 nm. Due to its longer polymer chains, NC2 is more prone to chain entanglement than the first nanocomposite system, NC1. Nevertheless, the larger microdomains were successfully guided by all three ring patterns. NC2 is more sensitive to pattern curvature than NC1, and the quality of the assembly decreased both across the set of patterns, from the largest (P200) to the smallest (P100), and within each pattern, from the outermost trench to the innermost.

The NC2 nanocomposite film on P200 had the same general trends of oscillating periodicity, defect density, and order parameter, that were observed in the series of NC1 samples. Within the more tightly-curved P150, the periodicity decrease within each trench was not balanced by a periodicity increase atop the mesas, and the defectivity increased overall. In the P100 sample, the microdomains were well-ordered only within the outermost trench, and the defectivity was high across the full pattern. These results suggest that, while the supramolecular nanocomposite can accommodate a variety of confinement widths, it remains sensitive to feature curvature.

In addition to tight pattern curvatures, the supramolecular nanocomposite could not accommodate nanoparticles larger than 10 nm or film thicknesses less than 50 nm. The NP size constraint is driven by the unfavorable polymer chain stretching that increases with particle size. At a certain NP size, the NP-related chain stretching is expected to dominate the template-related chain stretching, and the supramolecular system accommodates the NPs but ignores the underlying pattern. This is the other side of the system's robustness in that it almost always achieves an ordered state but may do so at the cost of the applied constraints. The system only exhibits global PDP redistribution when the film thickness is slightly greater than the trench depth and stays intact across the mesa features. Films thinner than 50 nm have relatively poor ordering because the supramolecules are fully isolated within the trenches and cannot use the unconfined mesa regions as PDP reservoirs. In this case, the blended system resembles a pure BCP, and would require more annealing to achieve alignment with the underlying pattern.

### Example 5

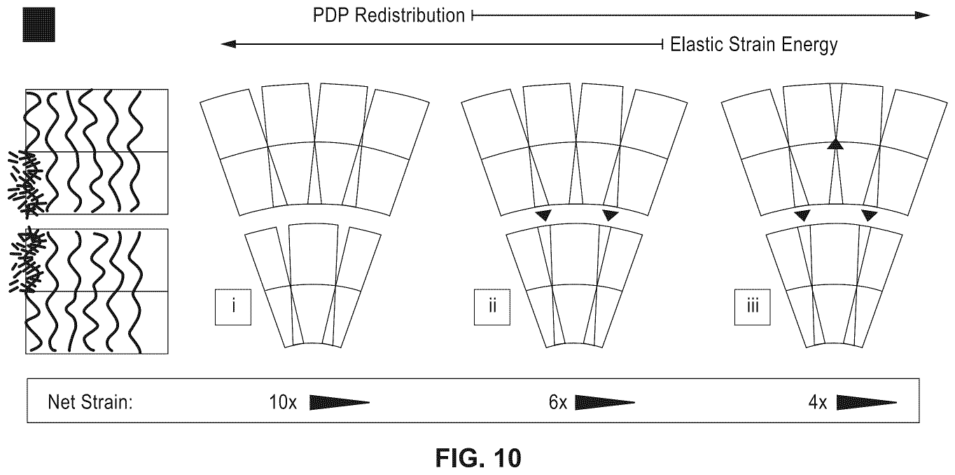

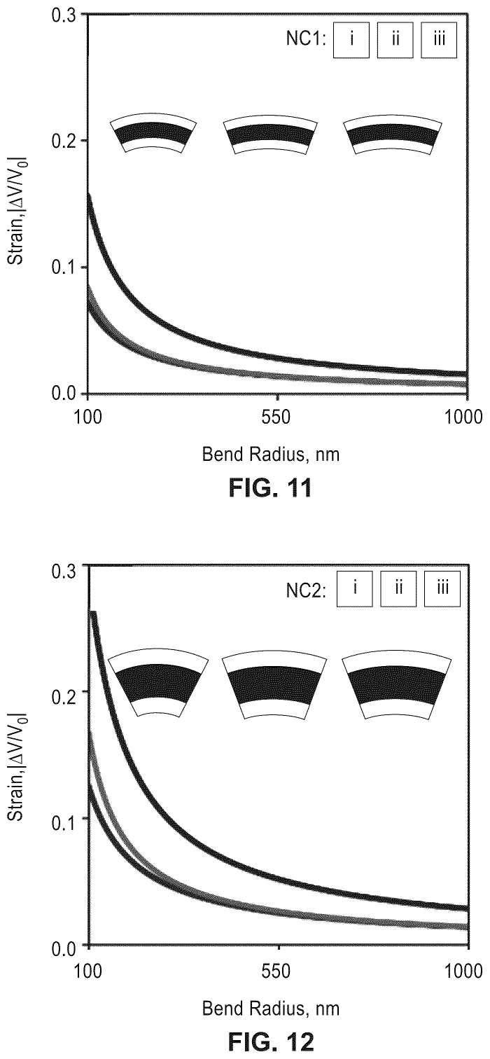

The energetics of bending microdomains were further evaluated. A schematic diagram of microdomain bending and three possible response modes: i, no PDP redistribution; ii, PDP redistributes within neighboring P4VP(PDP) microdomains; and iii, PDP redistributes within all neighboring microdomains is shown in FIG. 10. Strain vs. curvature radius for assemblies of NC1 and NC2 under redistribution modes i, ii, and iii are plotted in FIG. 11 and FIG. 12, respectively.

The PDP volume redistribution is determined by many competing energies: the polymer chain conformational entropy, the PDP mixing entropy, the block-block and block-NP interfacial enthalpies, and any enthalpies associated with PDP-polymer mixing. First, it was observed that the demand for PDP redistribution increases with curvature and with microdomain width, i.e. molecular weight as shown in FIG. 11 and FIG. 12. Second, the local PDP redistribution cannot entirely alleviate the bending energy. This suggests that the system will rely on global PDP redistribution that is well beyond the scale of individual microdomains to further decrease the energy cost of curved features. This is consistent with experimental observations: the sizes of the PDP-rich and PDP-poor domains are set by the template feature size, not the microdomain periodicity.

The propensity for small molecule redistribution of the supramolecular nanocomposite leads to a set of behaviors not typically seen with BCPs. The supramolecular nanocomposites exhibit rapid assembly kinetics, large (˜15%) periodicity changes, and spatially-patterned morphological shifts. They also respond differently to pattern-polymer incommensurability. In the BCP DSA system, the number of microdomains within a trench increases with a characteristic “stair-step” pattern as the trench width is continuously increased.

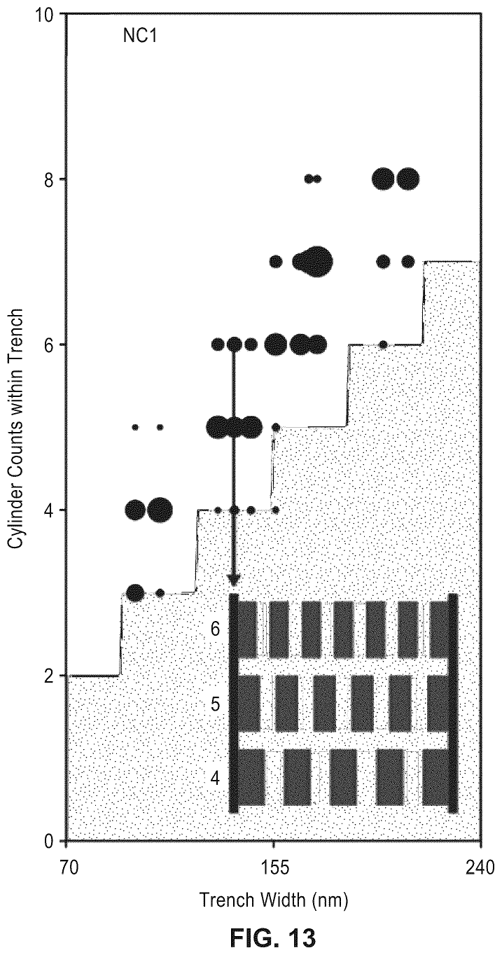

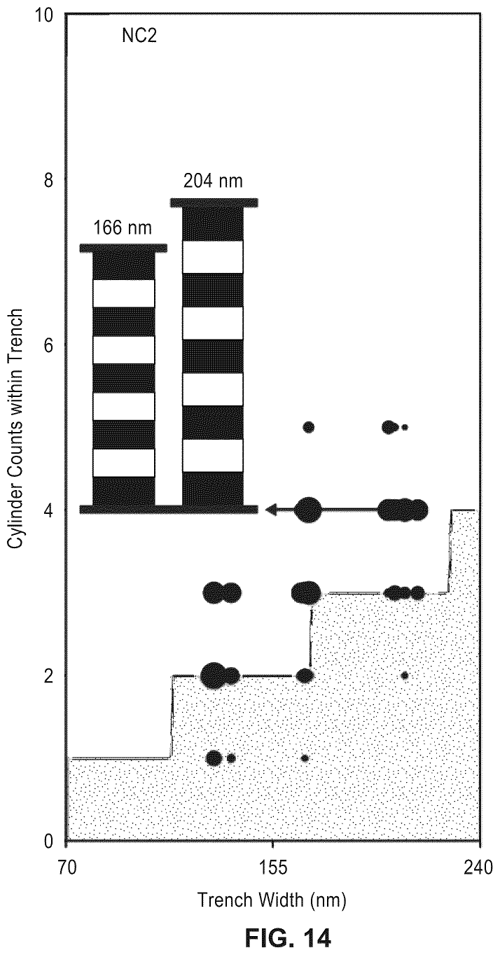

When BCPs are assembled within an incommensurate template, the microdomains reliably stretch or compress into the state nearest to the equilibrium periodicity. Degeneracy is only observed along the step verticals, where stretched states of n microdomains are energetically similar to compressed states of n+1 microdomains. The supramolecular nanocomposite deviates significantly from this BCP behavior. As a visual comparison, all observed states of the nanocomposites NC1 and NC2, respectively, on patterns P100, P150, and P200 are shown in FIG. 13 and FIG. 14, respectively. The gray stair-step pattern in the figures shows the commensurate state closest to the equilibrium periodicity for all trench widths. The marker size is scaled by the number of times a state was observed and the most common states are drawn with the largest markers.

The supramolecular assemblies have a high degree of structural degeneracy: for every trench width, 3 to 5 different states were observed. For example, a 140 nm trench, which is 4.5 equilibrium periods wide, was filled by 4, 5, or 6 cylinders. This behavior suggests that the energy penalty from distorting the microdomains is too small to drive the system into one equilibrium-like state.

Accordingly, the free energy landscape of the supramolecular nanocomposite is not funnel-shaped but is instead fairly flat with multiple local minima. Energy landscapes of this sort can be navigated by tuning the system's assembly kinetics and allow access to a diverse range of non-equilibrium states. Importantly, the flat energy landscape effect is not localized to the trenches and extends across the whole area affected by PDP redistribution. As a result, the unconfined mesas exhibit the same degree of structural degeneracy as shown with the trenches.

It can be seen that the DSA assembly of a supramolecular nanocomposite is a straightforward method for self-assembly of concentric NP rings within an organic matrix. Oscillations in the microdomain order parameter, periodicity, and defect density indicate that the supramolecule responds to incommensurability through small molecule rearrangement rather than polymer chain distortion. These versatile thin film devices are not limited by supramolecule periodicity or trench width due to the cooperative nature of the self-assembly process. Additionally, the use of small, discrete NPs instead of solid features presents new possibilities for incorporating interparticle coupling interactions into device designs. High-magnification microscopy and an FEM simulation were used to confirm that the patterned NPs successfully produce OAM. Successful DSA within a variety of curved patterns suggests that the same technique can be transferred to other geometries. The observed structural degeneracy is consistent with the hypothesis of a relatively flat free energy landscape, which is particularly suitable for kinetic control. Overall, the system provides a robust method for fabricating thin film devices for advanced optical applications, for example.

From the description herein, it will be appreciated that the present disclosure encompasses multiple implementations of the technology which include, but are not limited to, the following:

A method comprising: (a) preparing a patterned template of one or more mesas and trenches; (b) providing a solution of a solvent, a block copolymer, small molecules, and nanoparticles, the small molecules; and (c) depositing the solution on the patterned template forming a supramolecular nanocomposite with the nanoparticles by directed self-assembly.

The method of any preceding or following implementation, further comprising solvent vapor annealing the formed supramolecular nanocomposite.

The method of any preceding or following implementation, further comprising removing the supramolecular nanocomposite from the template.

The method of any preceding or following implementation, wherein the supramolecular nanocomposite is removed from the template by exfoliation.

The method of any preceding or following implementation, wherein the patterned template is created using electron beam lithography.

The method of any preceding or following implementation, wherein an upper surface of patterned template comprises a polymer layer.

The method of any preceding or following implementation, wherein the patterned template has a pattern selected from the group consisting of a single circular shape, a pair of concentric circles and three concentric circles.

The method of any preceding or following implementation, wherein the patterned template has an outer ring shape with a radius of between 150 nanometers and 1150 nanometers.

The method of any preceding or following implementation, wherein the solution is deposited on the patterned template by spin-coating to a thickness of between 50 nanometers and 70 nanometers.

The method of any preceding or following implementation, wherein the solvent comprises chloroform.

The method of any preceding or following implementation, wherein the block copolymer is selected from the group of copolymers consisting of polystyrene-b-poly(4-vinylpyridine) (PS-b-P4VP), PS(19 kDa)-b-P4VP(5.2 kDa) and PS(50 kDa)-b-P4VP(17 kDa).

The method of any preceding or following implementation, wherein the small molecules comprise organic small molecules.

The method of any preceding or following implementation, wherein the small molecules comprise 3-pentadecylphenol (PDP).

The method of any preceding or following implementation, wherein the nanoparticles are alkyl-passivated.

The method of any preceding or following implementation, wherein the nanoparticles are inorganic nanoparticles.

The method of any preceding or following implementation, wherein the nanoparticles comprise gold nanoparticles.

The method of any preceding or following implementation, wherein the nanoparticles have a diameter of between about 2.5 nanometers to 9.5 nanometers.

A method comprising: (a) providing a solution of at least one type of solvent, block copolymer, small molecules, nanoparticles, the small molecules configured to hydrogen bond to the block copolymer to form supramolecules; (b) providing a patterned template, the template defined by mesas and trenches having a depth from a surface of the template of about 50 nanometers to 75 nanometers; (c) depositing the solution on the template, forming a supramolecular nanocomposite with nanoparticles forming in the trenches by directed self-assembly; and (d) annealing the formed supramolecular nanocomposite.

The method of any preceding or following implementation, wherein the block copolymer is selected from the group of copolymers consisting of polystyrene-b-poly(4-vinylpyridine) (PS-b-P4VP), PS(19 kDa)-b-P4VP(5.2 kDa) and PS(50 kDa)-b-P4VP(17 kDa).

The method of any preceding or following implementation, wherein the nanoparticles have a diameter of between about 2.5 nanometers to 9.5 nanometers.

As used herein, the term “implementation” is intended to include, without limitation, embodiments, examples, or other forms of practicing the technology described herein.

As used herein, the singular terms “a,” “an,” and “the” may include plural referents unless the context clearly dictates otherwise. Reference to an object in the singular is not intended to mean “one and only one” unless explicitly so stated, but rather “one or more.”

Phrasing constructs, such as “A, B and/or C,” within the present disclosure describe where either A, B, or C can be present, or any combination of items A, B and C. Phrasing constructs indicating, such as “at least one of” followed by listing a group of elements, indicates that at least one of these groups of elements is present, which includes any possible combination of the listed elements as applicable.

References in this disclosure referring to “an embodiment,” “at least one embodiment” or similar embodiment wording indicates that a particular feature, structure, or characteristic described in connection with a described embodiment is included in at least one embodiment of the present disclosure. Thus, these various embodiment phrases are not necessarily all referring to the same embodiment, or to a specific embodiment which differs from all the other embodiments being described. The embodiment phrasing should be construed to mean that the particular features, structures, or characteristics of a given embodiment may be combined in any suitable manner in one or more embodiments of the disclosed apparatus, system, or method.

As used herein, the term “set” refers to a collection of one or more objects. Thus, for example, a set of objects can include a single object or multiple objects.

Relational terms such as first and second, top and bottom, upper and lower, left and right, and the like, may be used solely to distinguish one entity or action from another entity or action without necessarily requiring or implying any actual such relationship or order between such entities or actions.

The terms “comprises,” “comprising,” “has”, “having,” “includes”, “including,” “contains”, “containing” or any other variation thereof, are intended to cover a non-exclusive inclusion, such that a process, method, article, apparatus, or system, that comprises, has, includes, or contains a list of elements does not include only those elements but may include other elements not expressly listed or inherent to such process, method, article, apparatus, or system. An element proceeded by “comprises . . . a”, “has . . . a”, “includes . . . a”, “contains . . . a” does not, without more constraints, preclude the existence of additional identical elements in the process, method, article, apparatus, or system, that comprises, has, includes, contains the element.

As used herein, the terms “approximately”, “approximate”, “substantially”, “essentially”, and “about”, or any other version thereof, are used to describe and account for small variations. When used in conjunction with an event or circumstance, the terms can refer to instances in which the event or circumstance occurs precisely as well as instances in which the event or circumstance occurs to a close approximation. When used in conjunction with a numerical value, the terms can refer to a range of variation of less than or equal to ±10% of that numerical value, such as less than or equal to +5%, less than or equal to +4%, less than or equal to +3%, less than or equal to ±2%, less than or equal to ±1%, less than or equal to ±0.5%, less than or equal to +0.1%, or less than or equal to ±0.05%. For example, “substantially” aligned can refer to a range of angular variation of less than or equal to +10°, such as less than or equal to 5°, less than or equal to 4°, less than or equal to 3°, less than or equal to 2°, less than or equal to 1°, less than or equal to ±0.5°, less than or equal to ±0.1°, or less than or equal to ±0.05°.

Additionally, amounts, ratios, and other numerical values may sometimes be presented herein in a range format. It is to be understood that such range format is used for convenience and brevity and should be understood flexibly to include numerical values explicitly specified as limits of a range, but also to include all individual numerical values or sub-ranges encompassed within that range as if each numerical value and sub-range is explicitly specified. For example, a ratio in the range of about 1 to about 200 should be understood to include the explicitly recited limits of about 1 and about 200, but also to include individual ratios such as about 2, about 3, and about 4, and sub-ranges such as about 10 to about 50, about 20 to about 100, and so forth.

The term “coupled” as used herein is defined as connected, although not necessarily directly and not necessarily mechanically. A device or structure that is “configured” in a certain way is configured in at least that way but may also be configured in ways that are not listed.

Benefits, advantages, solutions to problems, and any element(s) that may cause any benefit, advantage, or solution to occur or become more pronounced are not to be construed as a critical, required, or essential feature or element of the technology described herein or any or all the claims.

In addition, in the foregoing disclosure various features may be grouped together in various embodiments for the purpose of streamlining the disclosure. This method of disclosure is not to be interpreted as reflecting an intention that the claimed embodiments require more features than are expressly recited in each claim. Inventive subject matter can lie in less than all features of a single disclosed embodiment.

The abstract of the disclosure is provided to allow the reader to quickly ascertain the nature of the technical disclosure. It is submitted with the understanding that it will not be used to interpret or limit the scope or meaning of the claims.

It will be appreciated that the practice of some jurisdictions may require deletion of one or more portions of the disclosure after the application is filed. Accordingly, the reader should consult the application as filed for the original content of the disclosure. Any deletion of content of the disclosure should not be construed as a disclaimer, forfeiture, or dedication to the public of any subject matter of the application as originally filed.

The following claims are hereby incorporated into the disclosure, with each claim standing on its own as a separately claimed subject matter.

Although the description herein contains many details, these should not be construed as limiting the scope of the disclosure, but as merely providing illustrations of some of the presently preferred embodiments. Therefore, it will be appreciated that the scope of the disclosure fully encompasses other embodiments which may become obvious to those skilled in the art.

All structural and functional equivalents to the elements of the disclosed embodiments that are known to those of ordinary skill in the art are expressly incorporated herein by reference and are intended to be encompassed by the present claims. Furthermore, no element, component, or method step in the present disclosure is intended to be dedicated to the public regardless of whether the element, component, or method step is explicitly recited in the claims. No claim element herein is to be construed as a “means plus function” element unless the element is expressly recited using the phrase “means for”. No claim element herein is to be construed as a “step plus function” element unless the element is expressly recited using the phrase “step for”.

TABLE 1
Compositions of Supramolecular Nanocomposites NC1 and NC2

| Supramo- | PS | P4VP | | | |
|---|---|---|---|---|---|
| lecular | molecular | molecular | | Equilibrium | 5 nm NP |
| nanocom- | weight | weight | 4VP:PDP | periodicity | loading |
| posite | [kDa] | [kDa] | ratio | [nm] | [vol %] |
| NC1 | 19 | 5.2 | 2 | 31 | 3 |
| NC2 | 50 | 17 | 2 | 57 | 3 |

TABLE 2
Dimensions of Lithographically-Patterned
Templates P100, P150, and P200

| | Trench width | Mesa width | Trench depth |
|---|---|---|---|
| Template | [nm] | [nm] | [nm] |
| P100 | 100 | 100 | 50 |
| P150 | 150 | 200 | 50 |
| P200 | 200 | 150 | 50 |

What is claimed is:

1. A method comprising:
(a) preparing a patterned template of one or more mesas and trenches;
(b) providing a solution of a solvent, a block copolymer, small molecules, and nanoparticles, the small molecules; and
(c) depositing the solution on the patterned template forming a supramolecular nanocomposite with the nanoparticles by directed self-assembly.

2. The method of claim 1, further comprising:
solvent vapor annealing the formed supramolecular nanocomposite.

3. The method of claim 1, further comprising:
removing the supramolecular nanocomposite from the template.

4. The method of claim 3, wherein the supramolecular nanocomposite is removed from the template by exfoliation.

5. The method of claim 1, wherein the patterned template is created using electron beam lithography.

6. The method of claim 1, wherein an upper surface of patterned template comprises a polymer layer.

7. The method of claim 1, wherein the patterned template has a pattern selected from the group consisting of a single circular shape, a pair of concentric circles and three concentric circles.

8. The method of claim 1, wherein the patterned template has an outer ring shape with a radius of between 150 nanometers and 1150 nanometers.

9. The method of claim 1, wherein the solution is deposited on the patterned template by spin-coating to a thickness of between 50 nanometers and 70 nanometers.

10. The method of claim 1, wherein the solvent comprises chloroform.

11. The method of claim 1, wherein the block copolymer is selected from the group of copolymers consisting of polystyrene-b-poly(4-vinylpyridine) (PS-b-P4VP), PS(19 kDa)-b-P4VP(5.2 kDa) and PS(50 kDa)-b-P4VP(17 kDa).

12. The method of claim 1, wherein the small molecules comprise organic small molecules.

13. The method of claim 12, wherein the small molecules comprise 3-pentadecylphenol (PDP).

14. The method of claim 1, wherein the nanoparticles are alkyl-passivated.

15. The method of claim 1, wherein the nanoparticles are inorganic nanoparticles.

16. The method of claim 1, wherein the nanoparticles comprise gold nanoparticles.

17. The method of claim 1, wherein said nanoparticles have a diameter of between about 2.5 nanometers to 9.5 nanometers.

18. A method comprising:
(a) providing a solution of at least one type of solvent, block copolymer, small molecules, nanoparticles, the small molecules configured to hydrogen bond to the block copolymer to form supramolecules;
(b) providing a patterned template, the template defined by mesas and trenches having a depth from a surface of the template of about 50 nanometers to 75 nanometers;
(c) depositing the solution on the template, forming a supramolecular nanocomposite with nanoparticles forming in the trenches by directed self-assembly; and
(d) annealing the formed supramolecular nanocomposite.

19. The method of claim 18, wherein the block copolymer is selected from the group of copolymers consisting of polystyrene-b-poly(4-vinylpyridine) (PS-b-P4VP), PS(19 kDa)-b-P4VP(5.2 kDa) and PS(50 kDa)-b-P4VP(17 kDa).

20. The method of claim 18, wherein said nanoparticles have a diameter of between about 2.5 nanometers to 9.5 nanometers.
